(19) United States
(12) Patent Application Publication
(10) Pub. No.: US 2026/0053030 A1
(43) Pub. Date: Feb. 19, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Eitaro MIYAKE, Tachikawa Tokyo (JP); Shun TAKEDA, Yokohama Kanagawa (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/362,605

(22) Filed: Oct. 20, 2025

Related U.S. Application Data
(63) Continuation of application No. PCT/JP2024/006606, filed on Feb. 22, 2024.

(30) Foreign Application Priority Data
Sep. 21, 2023 (JP) 2023-156405

(51) Int. Cl. H01L 23/498

(52) U.S. Cl. CPC H01L 23/49844; H01L 23/49811

(57) ABSTRACT

According to one embodiment, semiconductor device includes: a substrate; first to fourth conductive portions provided on the substrate; a first transistor having a drain and a source connected to the first and the second conductive portion, respectively; and second and third transistors each having a drain, a source, and a gate connected to the second, the third, and the fourth conductive portion, respectively; wherein the fourth conductive portion includes sixth and seventh portions to which each of the gate of the second and the third transistors is connected, respectively, and an eighth portion connecting the sixth portion and the seventh portion, and a shape of the eighth portion is different from a shape of the sixth and the seventh portions.

### CROSS-REFERENCE TO RELATED APPLICATIONS

This application is a Continuation Application of PCT Application No. PCT/JP2024/006606, filed Feb. 22, 2024; and based upon and claims the benefit of priority from Japanese Patent Application No. 2023-156405, filed Sep. 21, 2023, the entire contents of which are incorporated herein by reference.

### FIELD

Embodiments described herein relate generally to a semiconductor device.

### BACKGROUND

As a semiconductor device, a power module having a half-bridge configuration in which a plurality of transistors is connected in series is known. The power module is used in a traction inverter or the like.

### BRIEF DESCRIPTION OF THE DRAWINGS

FIG. 1 is a perspective view illustrating an example of an external structure of a semiconductor device according to a first embodiment.

FIG. 2 is a circuit diagram illustrating an example of a circuit configuration of the semiconductor device according to the first embodiment.

FIG. 3 is a perspective view illustrating an example of an internal structure of the semiconductor device according to the first embodiment.

FIG. 4 is a plan view illustrating an example of a planar layout of the semiconductor device according to the first embodiment.

FIG. 5 is a plan view illustrating an example of a planar layout of a semiconductor device according to a first modification of the first embodiment.

FIG. 6 is a plan view illustrating an example of a planar layout of a semiconductor device according to a second modification of the first embodiment.

FIG. 7 is a perspective view illustrating an example of an internal structure of a semiconductor device according to a second embodiment.

FIG. 8 is a plan view illustrating an example of a planar layout of the semiconductor device according to the second embodiment.

### DETAILED DESCRIPTION

In general, according to one embodiment, a semiconductor device include: a substrate; a first conductive portion, a second conductive portion, a third conductive portion, and a fourth conductive portion provided on the substrate; a first transistor having a drain electrically connected to the first conductive portion and a source electrically connected to the second conductive portion; and a second transistor and a third transistor each having a drain electrically connected to the second conductive portion, a source electrically connected to the third conductive portion, and a gate electrically connected to the fourth conductive portion; wherein the second conductive portion includes a first portion in contact with the second transistor and a second portion in contact with the third transistor and located on a side opposite to the first portion with respect to the first conductive portion, the third conductive portion includes a third portion to which a source of the second transistor is connected and located on a side opposite to the first conductive portion with respect to the first portion, a fourth portion to which a source of the third transistor is connected and located on a side opposite to the first conductive portion with respect to the second portion, and a fifth portion electrically connecting the third portion and the fourth portion, and the fourth conductive portion includes a sixth portion to which a gate of the second transistor is connected and located on a side opposite to the first conductive portion with respect to the third portion, a seventh portion to which a gate of the third transistor is connected and located on a side opposite to the first conductive portion with respect to the fourth portion, and an eighth portion electrically connecting the sixth portion and the seventh portion, and a shape of the eighth portion is different from a shape of the sixth portion and a shape of the seventh portion.

Hereinafter, embodiments will be described with reference to the drawings. In the following description, components having substantially the same functions and configurations are denoted by the same reference numerals. In a case where it is not necessary to distinguish elements represented by reference numerals including the same character from each other, each of these elements is referred to by a reference numeral including only a character.

In the following description, a first element is “connected” to another second element includes that the first element is connected to the second element either indirectly via an intermediate element that is always or selectively conductive, or directly without an intermediate element.

### 1. First Embodiment

A first embodiment will be described. Hereinafter, a power module will be described as an example of a semiconductor device according to the first embodiment. The power module is applied to, for example, a traction inverter or the like.

A configuration of the semiconductor device according to the first embodiment will be described.

First, an external structure of the semiconductor device according to the first embodiment will be described.

FIG. 1 is a perspective view illustrating an example of an external structure of the semiconductor device according to the first embodiment. A semiconductor device 1 includes an enclosure structure in which a package provided on a substrate 10 is sealed with a sealing resin 100.

The substrate 10 is, for example, a ceramic substrate. In the following description, a plane on which the substrate 10 spreads is referred to as an XY plane. In the XY plane, a longitudinal direction and a lateral direction of the substrate 10 are defined as an X direction and a Y direction, respectively. A direction intersecting the XY plane is defined as a Z direction or an upward direction. The directions opposite to the X direction, the Y direction, and the Z direction are defined as a −X direction, a −Y direction, and a −Z direction, respectively. The −Z direction is defined as a downward direction.

The sealing resin 100 contains, for example, an epoxy resin. The sealing resin 100 provides insulation between conductors in the semiconductor device 1. In addition, the sealing resin 100 protects components of the semiconductor device 1 from physical disturbance.

The semiconductor device 1 further includes terminals P, N, AC, HS, HG, LS, and LG, and a heat sink 40.

The terminals P, N, AC, HS, HG, LS, and LG are end portions of metal components that electrically connect an external device of the semiconductor device 1 and an internal circuit configuration. The semiconductor device 1 includes two terminals N and one terminals P, AC, HG, HS, LG, and LS. These terminals are provided apart from each other.

The terminal P is an input terminal. The terminal P is connected to a positive terminal of an external DC power supply. The terminal P is provided so as to extend in the −Y direction from the −Y side surface portion of the housing structure formed by the sealing resin 100.

The two terminals N are input terminals. The two terminals N are connected to a negative terminal of an external DC power supply. The two terminals N are electrically connected to each other. The two terminals N are arranged side by side in the X direction so as to sandwich the terminal P, and are provided so as to extend in the −Y direction from the −Y side surface portion of the housing structure formed by the sealing resin 100.

The terminal AC is an output terminal. An alternating current is output to an external device through the terminal AC. The terminal AC is provided so as to extend in the Y direction from the Y side surface portion of the housing structure formed by the sealing resin 100.

The terminals HG and LG are control terminals. The terminals HG and LG are, for example, terminals for controlling whether to drive semiconductor elements included in a circuit configuration in the semiconductor device 1. The terminals HG and LG are arranged side by side with the terminal AC in the X direction, and are provided so as to extend in the Y direction from the Y side surface portion of the housing structure formed by the sealing resin 100.

The terminals HS and LS are control terminals. The terminal HS is, for example, a terminal serving as a reference of the voltage of the terminal HG. The terminal LS is, for example, a terminal serving as a reference of the voltage of the terminal LG. The terminals HS and LS are arranged side by side with the terminals AC, HG, and LG in the Y direction, and are provided so as to extend in the Y direction from the Y side surface portion of the housing structure formed by the sealing resin 100.

The heat sink 40 has, for example, a plate-like shape containing copper. The heat sink 40 is in contact with a lower surface of the substrate 10. The heat sink 40 has a role of releasing heat generated inside the substrate 10 to the outside and cooling the semiconductor device 1.

Next, a circuit configuration of the semiconductor device according to the first embodiment will be described.

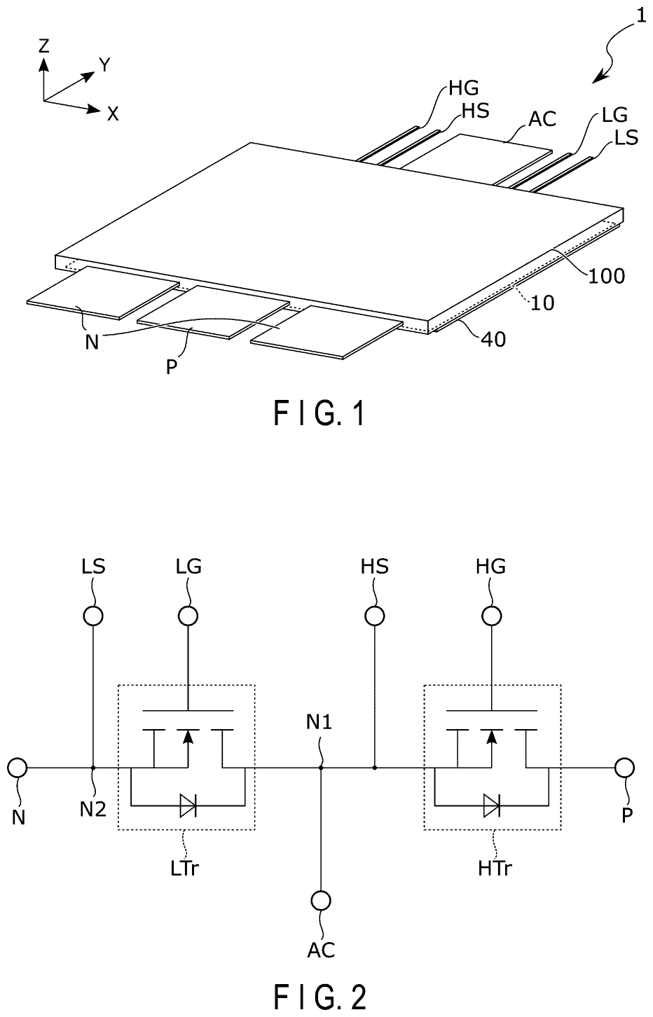

FIG. 2 is a circuit diagram illustrating an example of a circuit configuration of the semiconductor device according to the first embodiment. The semiconductor device 1 further includes a high-side transistor HTr and a low-side transistor LTr as electrical elements included in the internal circuit configuration.

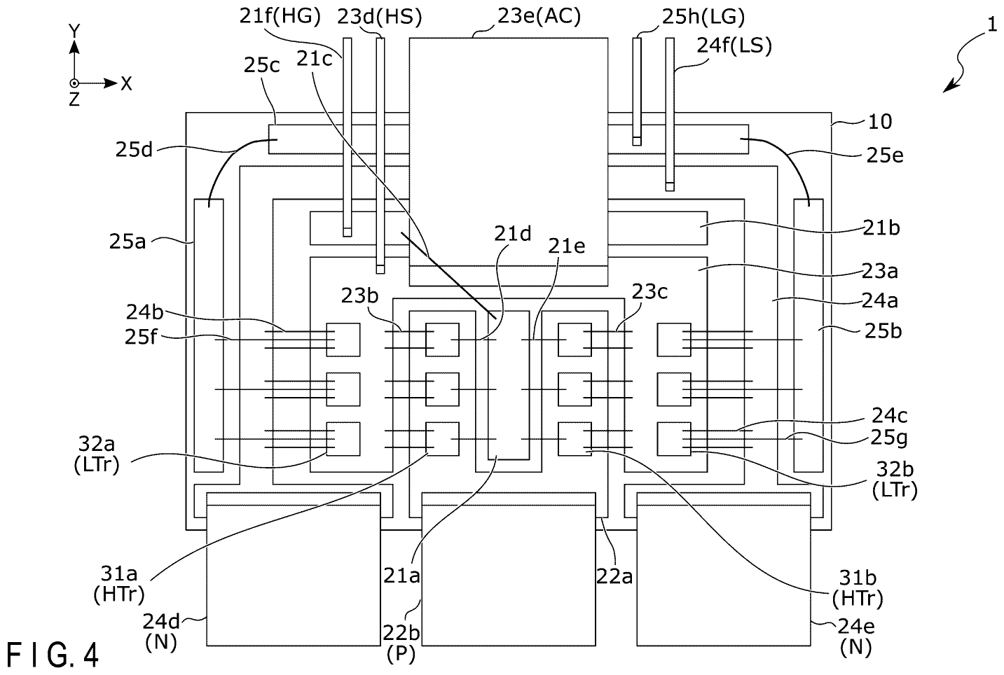

The high-side transistor HTr and the low-side transistor LTr are, for example, N-type metal-oxide-semiconductor field-effect transistors (MOSFET). As illustrated in FIG. 4, the high-side transistor HTr and the low-side transistor LTr are connected in series via a node N1. That is, the high-side transistor HTr and the low-side transistor LTr configure a half bridge circuit. The semiconductor device 1 is a module having a 2-in-1 configuration including a half bridge circuit in one module. In the following description, components related to the operation of the high-side transistor HTr are denoted by “high-side”, and components related to the operation of the low-side transistor LTr are denoted by “low-side” for distinction.

A drain terminal of the high-side transistor HTr is connected to the terminal P.

A source terminal of the high-side transistor HTr is connected to a drain terminal of the low-side transistor LTr via the node N1. In addition, the terminal HS is connected to the node N1. That is, the terminal HS is a terminal connected to a high-side source end. A voltage applied to the source of the high-side transistor HTr and the drain of the low-side transistor LTr is monitored via the terminal HS. Furthermore, the terminal AC is connected to the node N1. For example, the AC signal is output from the terminal AC to the outside by controlling driving of the high-side transistor HTr and the low-side transistor LTr.

The terminal HG is connected to a gate terminal of the high-side transistor HTr. That is, the terminal HG is a terminal connected to a high-side gate end. Whether to drive the high-side transistor HTr is controlled via the terminal HG. In a case where the voltage applied to the terminal HG is higher than a threshold voltage of the high-side transistor HTr, the drain terminal and the source terminal of the high-side transistor HTr are electrically connected. In a case where the voltage applied to the terminal HG is lower than the threshold voltage of the high-side transistor HTr, the drain terminal and the source terminal of the high-side transistor HTr are electrically insulated.

A source terminal of the low-side transistor LTr is connected to the two terminals N via the node N2. In addition, the terminal LS is connected to the node N2. That is, the terminal LS is a terminal connected to a low-side source end. The voltage applied to the source of the low-side transistor LTr is monitored via the terminal LS.

A gate terminal of the low-side transistor LTr is connected to the terminal LG. That is, the terminal LG is a terminal connected to a low-side gate end. Whether to drive the low-side transistor LTr is controlled via the terminal LG. In a case where the voltage applied to the terminal LG is higher than a threshold voltage of the low-side transistor LTr, the drain terminal and the source terminal of the low-side transistor LTr are electrically connected. In a case where the voltage applied to the terminal LG is lower than the threshold voltage of the low-side transistor LTr, the drain terminal and the source terminal of the low-side transistor LTr are electrically insulated.

With the above configuration, the semiconductor element inside the semiconductor device 1 is controlled by a voltage supplied from the outside of the semiconductor device 1, and generates and outputs an AC signal to the outside.

Next, an internal structure of the semiconductor device according to the first embodiment will be described.

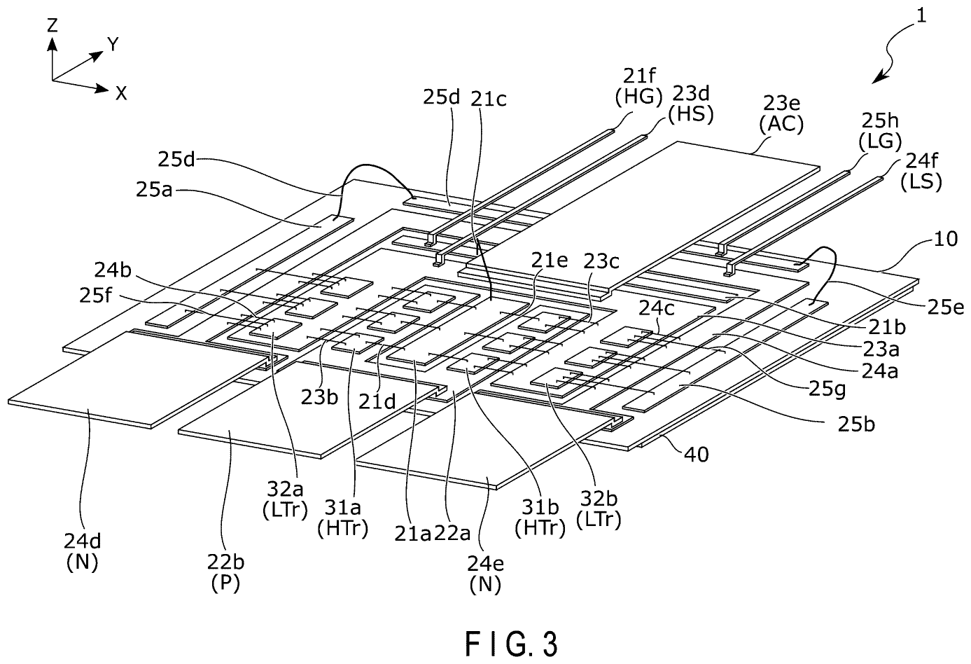

FIG. 3 is a perspective view illustrating an example of an internal structure of the semiconductor device according to the first embodiment. FIG. 4 is a plan view illustrating an example of a planar layout of the semiconductor device according to the first embodiment. In FIGS. 3 and 4, the sealing resin 100 is omitted. A structure of the semiconductor device 1 will be described with reference to FIGS. 3 and 4.

As illustrated in FIGS. 3 and 4, the semiconductor device 1 further includes conductive portions 21, 22, 23, 24, and 25. Furthermore, the semiconductor device 1 includes a plurality of transistors 31a and 31b as transistors corresponding to the high-side transistors HTr, and includes a plurality of transistors 32a and 32b as transistors corresponding to the low-side transistors LTr.

In the following description, a “conductor pattern” means a flat conductor disposed on an upper surface of the substrate 10 to be separated from each other. The “wire” means a linear bonding wire that electrically connects conductor patterns. The “terminal member” means a conductive member that electrically connects the conductor pattern and a device existing outside the semiconductor device 1.

The “wire” has a shape different from that of the “conductor pattern”. Therefore, the “wire” and the “conductor pattern” are significantly different in electrical characteristics such as inductance. Specifically, the inductance of the “wire” connecting two points is higher than the inductance of the “conductor pattern” connecting the same two points.

The conductive portion 21 is a conductor group corresponding to the wiring of the high-side gate. The conductive portion 21 includes conductor patterns 21a and 21b, a wire 21c, a plurality of wires 21d and 21e, and a terminal member 21f. The conductor pattern 21a is provided at a central portion on the substrate 10. The conductor pattern 21b extends in the X direction and is provided on the substrate 10 so as to be aligned with the conductor pattern 21a in the Y direction. The wire 21c has a first end in contact with the conductor pattern 21a and a second end in contact with the conductor pattern 21b. The wire 21c is provided so as to pass over a third portion of a conductor pattern 23a and a terminal member 23e to be described later. Each of the plurality of wires 21d has a first end in contact with the conductor pattern 21a and a second end in contact with a gate electrode (not illustrated) provided on the upper surface of the corresponding transistor among the plurality of transistors 31a. Each of the plurality of wires 21e has a first end in contact with the conductor pattern 21a and a second end in contact with a gate electrode (not illustrated) provided on the upper surface of the corresponding transistor among the plurality of transistors 31b. The terminal member 21f has a first end in contact with the conductor pattern 21b and a second end functioning as the terminal HG. The terminal member 21f passes over a third portion of a conductor pattern 24a and a conductor pattern 25c to be described later, and extends toward the outside of the semiconductor device 1.

The conductive portion 22 is a conductor group corresponding to the high-side drain. The conductive portion 22 includes a conductor pattern 22a and a terminal member 22b. The conductor pattern 22a includes a first portion, a second portion, and a third portion. The first portion and the second portion of the conductor pattern 22a are provided so as to sandwich the conductor pattern 21a in the X direction. The first portion of the conductor pattern 22a is in contact with a drain electrode (not illustrated) provided on the lower surface of each of the plurality of transistors 31a. The second portion of the conductor pattern 22a is in contact with a drain electrode (not illustrated) provided on the lower surface of each of the plurality of transistors 31b. The third portion of the conductor pattern 22a is provided to extend in the X direction on a side opposite to the conductor pattern 21b with respect to the conductor pattern 21a, and has a first end in contact with the first portion of the conductor pattern 21a and a second end in contact with the second portion of the conductor pattern 21a. The terminal member 22b has a first end in contact with the third portion of the conductor pattern 22a and a second end functioning as the terminal P. The terminal member 22b extends toward the outside of the semiconductor device 1.

The conductive portion 23 is a conductor group corresponding to the high-side source and the low-side drain. The conductive portion 23 includes the conductor pattern 23a, a plurality of wires 23b and 23c, and terminal members 23d and 23e. The conductor pattern 23a includes a first portion, a second portion, and a third portion. The first portion and the second portion of the conductor pattern 23a are provided so as to sandwich the conductor pattern 21a and the first portion and the second portion of the conductor pattern 22a in the X direction. The first portion of the conductor pattern 23a is in contact with a drain electrode (not illustrated) provided on the lower surface of each of the plurality of transistors 32a. The second portion of the conductor pattern 23a is in contact with a drain electrode (not illustrated) provided on the lower surface of each of the plurality of transistors 32b. The third portion of the conductor pattern 23a is provided to extend in the X direction between the conductor pattern 21a and the conductor pattern 21b, and has a first end in contact with the first portion of the conductor pattern 23a and a second end in contact with the second portion of the conductor pattern 23a. Each of the plurality of wires 23b has a first end in contact with the first portion of the conductor pattern 23a and a second end in contact with a source electrode (not illustrated) provided on the upper surface of the corresponding transistor among the plurality of transistors 31a. Each of the plurality of wires 23c has a first end in contact with the second portion of the conductor pattern 23a and a second end in contact with a source electrode (not illustrated) provided on the upper surface of the corresponding transistor among the plurality of transistors 31b. In FIGS. 3 and 4, two wires 23b and 23c are provided for each source electrode of the corresponding transistor among the plurality of transistors 31a or 31b, but the present invention is not limited thereto. One or more wires 23b and 23c may be provided for each source electrode of the corresponding transistor among the plurality of transistors 31a or 31b. The terminal member 23d has a first end in contact with the third portion of the conductor pattern 23a and a second end functioning as the terminal HS. The terminal member 23e has a first end in contact with the third portion of the conductor pattern 23a and a second end functioning as the terminal AC. The terminal members 23d and 23e pass over the conductor pattern 21b, the third portion of the conductor pattern 24a to be described later, and the conductor pattern 25c to be described later, and extend toward the outside of the semiconductor device 1.

The conductive portion 24 is a conductor group corresponding to the low-side source. The conductive portion 24 includes the conductor pattern 24a, a plurality of wires 24b and 24c, and terminal members 24d, 24e, and 24f. The conductor pattern 24a includes a first portion, a second portion, and a third portion. The first portion and the second portion of the conductor pattern 24a are provided so as to sandwich the conductor pattern 21a, the first portion and the second portion of the conductor pattern 22a, and the first portion and the second portion of the conductor pattern 23a in the X direction. The third portion of the conductor pattern 24a is provided to extend in the X direction on a side opposite to the third portion of the conductor pattern 23a with respect to the conductor pattern 21b, and has a first end in contact with the first portion of the conductor pattern 24a and a second end in contact with the second portion of the conductor pattern 24a. Each of the plurality of wires 24b has a first end in contact with the first portion of the conductor pattern 24a and a second end in contact with a source electrode (not illustrated) provided on the upper surface of the corresponding transistor among the plurality of transistors 32a. Each of the plurality of wires 24c has a first end in contact with the second portion of the conductor pattern 24a and a second end in contact with a source electrode (not illustrated) provided on the upper surface of the corresponding transistor among the plurality of transistors 32b. In FIGS. 3 and 4, two wires 24b and 24c are provided for each source electrode of the corresponding transistor among the plurality of transistors 32a or 32b, but the present invention is not limited thereto. One or more wires 24b and 24c may be provided for each source electrode of the corresponding transistor among the plurality of transistors 32a or 32b. The terminal member 24d has a first end in contact with the first portion of the conductor pattern 24a and a second end functioning as the terminal N. The terminal member 24e has a first end in contact with the second portion of the conductor pattern 24a and a second end functioning as the terminal N. The terminal members 24d and 24e extend side by side toward the outside of the semiconductor device 1. The terminal member 24f has a first end in contact with the third portion of the conductor pattern 24a and a second end functioning as the terminal LS. The terminal member 24f passes over a conductor pattern 25c to be described later and extends toward the outside of the semiconductor device 1.

The conductive portion 25 is a conductor group corresponding to the low-side gate. The conductive portion 25 includes conductor patterns 25a, 25b, and 25c, wires 25d and 25e, a plurality of wires 25f and 25g, and a terminal member 25h. The conductor patterns 25a and 25b are provided so as to sandwich the conductor pattern 21a, the first portion and the second portion of the conductor pattern 22a, the first portion and the second portion of the conductor pattern 23a, and the first portion and the second portion of the conductor pattern 24a in the X direction. The conductor pattern 25c is provided to extend in the X direction on a side opposite to the conductor pattern 21b with respect to the third portion of the conductor pattern 24a. The wire 25d has a first end in contact with the conductor pattern 25a and a second end in contact with the conductor pattern 25c. The wire 25e has a first end in contact with the conductor pattern 25b and a second end in contact with the conductor pattern 25c. The wires 25d and 25e are provided so as to pass only over the substrate 10 without passing over the other conductors. Each of the plurality of wires 25f has a first end in contact with the conductor pattern 25a and a second end in contact with a gate electrode (not illustrated) provided on the upper surface of the corresponding transistor among the plurality of transistors 32a. The plurality of wires 25f is provided so as to pass over the first portion of the conductor pattern 24a. Each of the plurality of wires 25g has a first end in contact with the conductor pattern 25b and a second end in contact with a gate electrode (not illustrated) provided on the upper surface of the corresponding transistor among the plurality of transistors 32b. The plurality of wires 25g is provided so as to pass over the second portion of the conductor pattern 24a. The terminal member 25h has a first portion in contact with the conductor pattern 25c and a second end functioning as the terminal LG.

A plurality of transistors 31a is arranged side by side in the Y direction on the upper surface of the first portion of the conductor pattern 22a. A plurality of transistors 31b is arranged side by side in the Y direction on the upper surface of the second portion of the conductor pattern 22a. A plurality of transistors 32a is arranged side by side in the Y direction on the upper surface of the first portion of the conductor pattern 23a. A plurality of transistors 32b is arranged side by side in the Y direction on the upper surface of the second portion of the conductor pattern 23a. In the examples of FIGS. 3 and 4, three sets of each of the transistors 31a, 31b, 32a, and 32b are provided, but one or more sets of the transistors 31a and 31b may be provided in total, and one or more sets of each of the transistors 32a and 32b may be provided.

With the configuration according to the first embodiment, oscillation of the transistor can be suppressed. This will be described in detail below.

When there are two transistors that share the potential of the connection destination of each terminal of the drain, the source, and the gate, the inductance seen in the circuit connecting the source terminals of the transistors is referred to as source inductance (Ls), and the inductance seen in the circuit connecting the gate terminals of the transistors is referred to as gate inductance (Lg).

When a large-capacity semiconductor device is manufactured, a plurality of transistors having the same function may be dispersedly arranged in one package in order to enhance heat dissipation efficiency. In a case where a plurality of transistors that is dispersedly arranged and has the same function is mounted on the same conductor pattern, a distance of the conductor pattern tends to be long, and the inductance (for example, the source inductance) of the conductor pattern tends to be high. When the source inductance increases, the transistor may oscillate during switching. Oscillation of the transistor may lead to malfunction of the transistor, an increase in loss, or destruction of the transistor in some cases, which is undesirable.

One of the methods for suppressing the oscillation of the transistors is to increase a ratio (Lg/Ls) of the gate inductance to the source inductance of the circuit that connects the terminals of the transistors. In a case where the Lg/Ls ratio takes a large value, oscillation of the transistor is suppressed.

In the case of the configuration according to the first embodiment, the plurality of low-side transistors is disposed apart from each other in one package so as to sandwich the plurality of high-side transistors in the X direction. For this reason, the conductor pattern 24a connecting the source terminals of the respective low-side transistors extends long in the X direction, and as a result, the low-side source inductance increases. Therefore, in order to increase the Lg/Ls ratio, it is desirable to increase the low-side gate inductance.

According to the configuration of the first embodiment, in the low-side transistor, the conductor pattern in the circuit connecting the gate terminal of the transistor 32a and the gate terminal of the transistor 32b is divided into a plurality of pieces (conductor patterns 25a, 25b, and 25c), and the wires 25d and 25e having high inductance are provided as the conductors connecting the conductor patterns. With this configuration, the gate inductance in the circuit connecting the gate terminal of the transistor 32a and the gate terminal of the transistor 32b can be increased. As a result, the Lg/Ls ratio can be increased, and the oscillation of the low-side transistor can be suppressed.

In addition, in the configuration according to the first embodiment, a plurality of transistors 31a, 31b, 32a, and 32b is dispersedly arranged on both sides of the conductor pattern 21a. With this configuration, the transistors as heat sources are dispersed, so that the heat dissipation efficiency of the semiconductor device increases.

The semiconductor device 1 according to the first embodiment described above can be variously modified. Modifications will be described below.

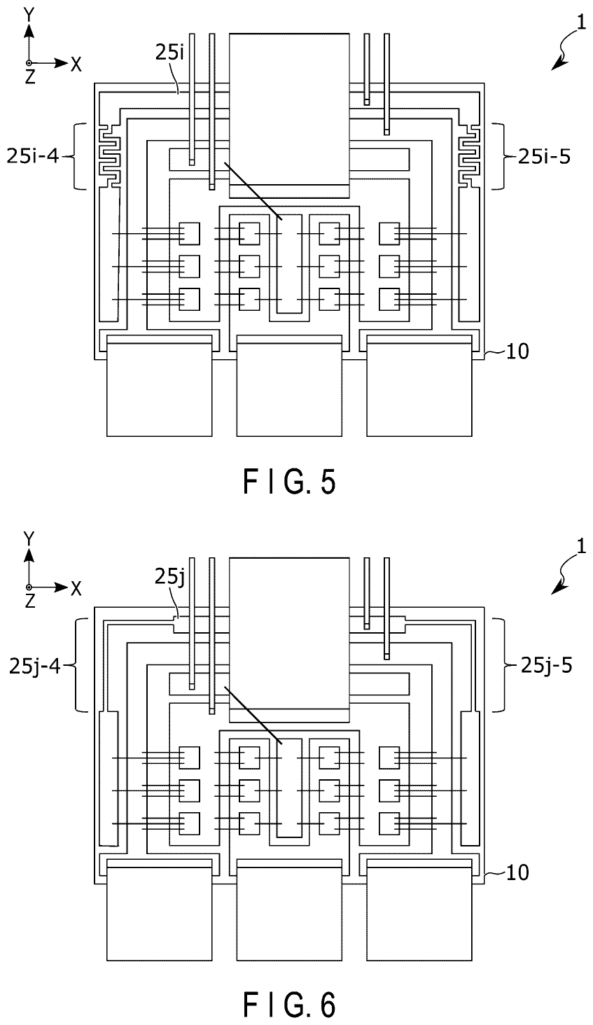

FIG. 5 is a plan view illustrating an example of a planar layout of a semiconductor device according to a first modification of the first embodiment. FIG. 6 is a plan view illustrating an example of a planar layout of a semiconductor device according to a second modification of the first embodiment.

As illustrated in FIGS. 5 and 6, the configuration for connecting the conductor pattern 25a and the conductor pattern 25c and the configuration for connecting the conductor pattern 25b and the conductor pattern 25c are not limited to wires.

In the first modification illustrated in FIG. 5, the conductive portion 25 includes a conductor pattern 25i instead of the conductor patterns 25a, 25b, and 25c and the wires 25d and 25e. The conductor pattern 25i includes a first portion, a second portion, a third portion, a fourth portion (251-4), and a fifth portion (251-5). The first portion, the second portion, the third portion, the fourth portion, and the fifth portion of the conductor pattern 25i correspond to the conductor pattern 25a, the conductor pattern 25b, the conductor pattern 25c, the wire 25d, and the wire 25e in the first embodiment, respectively. The first portion and the second portion of the conductor pattern 25i are provided so as to sandwich the conductor pattern 21a, the first portion and the second portion of the conductor pattern 22a, the first portion and the second portion of the conductor pattern 23a, and the first portion and the second portion of the conductor pattern 24a in the X direction. The third portion of the conductor pattern 25i is provided to extend in the X direction on a side opposite to the conductor pattern 21b with respect to the third portion of the conductor pattern 24a. The fourth portion and the fifth portion of the conductor pattern 25i are flat conductors having a meandering shape folded a plurality of times. The fourth portion of the conductor pattern 25i has a first end in contact with the first portion of the conductor pattern 25i and a second end in contact with the third portion of the conductor pattern 251. The fifth portion of the conductor pattern 25i has a first end in contact with the second portion of the conductor pattern 25i and a second end in contact with the third portion of the conductor pattern 251. The fourth portion and the fifth portion of the conductor pattern 25i having a meandering shape folded a plurality of times have inductance higher than that of a conductor pattern having a straight shape.

In the configuration illustrated in the first modification, the low-side gate inductance increases due to an increase in inductance caused by the shapes of the fourth portion and the fifth portion of the conductor pattern 25i. As a result, the Lg/Ls ratio can be increased, and the oscillation of the low-side transistor can be suppressed.

In the second modification illustrated in FIG. 6, the conductive portion 25 includes a conductor pattern 25j instead of the conductor patterns 25a, 25b, and 25c and the wires 25d and 25e. The conductor pattern 25j includes a first portion, a second portion, a third portion, a fourth portion (25j-4), and a fifth portion (25j-5). The first portion, the second portion, the third portion, the fourth portion, and the fifth portion of the conductor pattern 25j correspond to the conductor pattern 25a, the conductor pattern 25b, the conductor pattern 25c, the wire 25d, and the wire 25e in the first embodiment, respectively. The first portion and the second portion of the conductor pattern 25j are provided so as to sandwich the conductor pattern 21a, the first portion and the second portion of the conductor pattern 22a, the first portion and the second portion of the conductor pattern 23a, and the first portion and the second portion of the conductor pattern 24a in the X direction. The third portion of the conductor pattern 25j is provided to extend in the X direction on a side opposite to the conductor pattern 21b with respect to the third portion of the conductor pattern 24a. The fourth portion and the fifth portion of the conductor pattern 25j are flat conductors having a shorter width length than that of the first portion, the second portion, and the third portion of the conductor pattern 25j. The fourth portion of the conductor pattern 25j has a first end in contact with the first portion of the conductor pattern 25j and a second end in contact with the third portion of the conductor pattern 25j. The fifth portion of the conductor pattern 25j has a first end in contact with the second portion of the conductor pattern 25j and a second end in contact with the third portion of the conductor pattern 25j. The fourth portion and the fifth portion of the conductor pattern 25j having a shape in which the length of the conductor pattern width is short have higher inductance than that of the first portion, the second portion, and the third portion of the conductor pattern 25j.

In the configuration shown in the second modification, the low-side gate inductance increases due to an increase in inductance caused by the shapes of the fourth portion and the fifth portion of the conductor pattern 25j. As a result, the Lg/Ls ratio can be increased, and the oscillation of the low-side transistor can be suppressed.

In addition to the first modification and the second modification, various modifications can be considered for the configuration corresponding to the wires 25d and 25e in the first embodiment. The shape is not limited as long as the low-side gate inductance is increased by the configuration corresponding to the wires 25d and 25e in the first embodiment.

### 2. Second Embodiment

Next, a second embodiment will be described. Hereinafter, a configuration different from that of the first embodiment will be mainly described.

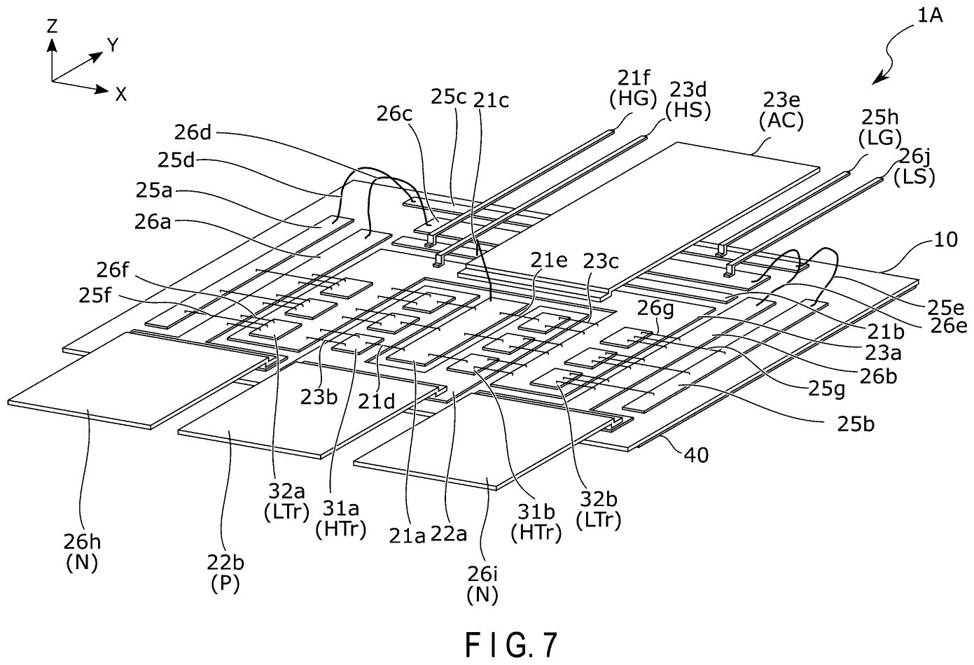

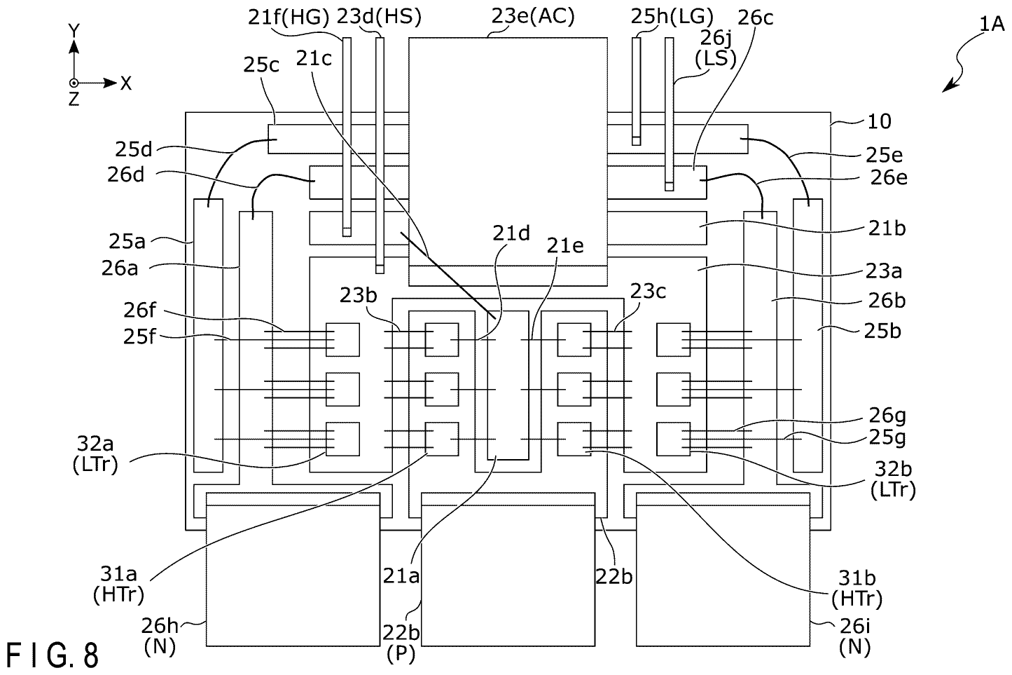

FIG. 7 is a perspective view illustrating an example of an internal structure of a semiconductor device according to a second embodiment. FIG. 8 is a plan view illustrating an example of a planar layout of the semiconductor device according to the second embodiment. In FIGS. 7 and 8, a sealing resin 100 is omitted. A structure of a semiconductor device 1A will be described with reference to FIGS. 7 and 8.

As illustrated in FIGS. 7 and 8, the semiconductor device 1A includes a conductive portion 26 instead of the conductive portion 24 in the first embodiment. Note that the configuration of the semiconductor device 1A excluding the conductive portion 26 is the same as the configuration of the first embodiment excluding the conductive portion 24.

The conductive portion 26 is a conductor group corresponding to the low-side source. The conductive portion 26 includes conductor patterns 26a, 26b, and 26c, wires 26d and 26e, a plurality of wires 26f and 26g, and terminal members 26h, 26i, and 26j. Conductor patterns 26a and 26b correspond to the first portion and the second portion of the conductor pattern 24a in the first embodiment. The conductor pattern 26c and the wires 26d and 26e correspond to the third portion of the conductor pattern 24a in the first embodiment. The plurality of wires 26f and 26g corresponds to the plurality of wires 24b and 24c in the first embodiment. The terminal members 26h, 26i, and 26j correspond to the terminal members 24d, 24e, and 24f in the first embodiment.

The conductor patterns 26a and 26b are provided so as to sandwich the conductor pattern 21a, the first portion and the second portion of the conductor pattern 22a, and the first portion and the second portion of the conductor pattern 23a in the X direction. The conductor pattern 26c is provided to extend in the X direction on a side opposite to the third portion of the conductor pattern 23a with respect to the conductor pattern 21b. The wire 26d has a first end in contact with the conductor pattern 26a and a second end in contact with the conductor pattern 26c. The wire 26e has a first end in contact with the conductor pattern 26b and a second end in contact with the conductor pattern 26c. The wires 26d and 26e are provided so as to pass only over the substrate 10 without passing over the other conductors. Each of the plurality of wires 26f has a first end in contact with the conductor pattern 26a and a second end in contact with the source electrode provided on the upper surface of the corresponding transistor among the plurality of transistors 32a. Each of the plurality of wires 26g has a first end in contact with the conductor pattern 26b and a second end in contact with the source electrode provided on the upper surface of the corresponding transistor among the plurality of transistors 32b. In FIGS. 7 and 8, two wires 26f and 26g are provided for each source electrode of the corresponding transistor among the plurality of transistors 32a or 32b, but one or more wires 26f and 26g may be provided for each source electrode of the corresponding transistor among the plurality of transistors 32a or 32b. The terminal member 26h has a first end in contact with the conductor pattern 26a and a second end functioning as the terminal N. The terminal member 26i has a first end in contact with the conductor pattern 26b and a second end functioning as the terminal N. The terminal member 26j has a first end in contact with the conductor pattern 26c and a second end functioning as the terminal LS. The terminal member 26j passes above the conductor pattern 25c and extends toward the outside of the semiconductor device 1A.

The wires 25d and 26d have substantially the same thickness and length. The wires 25d and 26d are arranged side by side with each other. Specifically, a distance between the wire 25d and the wire 26d is designed to include a portion having a distance of about 0.1 mm and 2 mm or less at the maximum. However, the wires 25d and 26d do not touch each other.

The wires 25e and 26e have substantially the same thickness and length. The wires 25e and 26e are arranged side by side with each other. Specifically, a distance between the wire 25e and the wire 26e are designed to include a portion having a distance of about 0.1 mm and 2 mm or less at the maximum. However, the wires 25e and 26e do not touch each other.

Further, in the semiconductor device 1A according to the present embodiment, circuits connected to the two terminals N are short-circuited to each other in an external configuration (not illustrated).

With the configuration according to the second embodiment, it is possible to suppress delay of a control signal input from the outside. Furthermore, with the configuration according to the second embodiment, oscillation of the transistor can be suppressed as in the first embodiment. This will be described in detail below.

In a circuit that connects the gate terminals of the plurality of low-side transistors LTr to each other, when a gate inductance Lg increases, a resistance in the circuit also increases. Therefore, there is a possibility that the control signal sent from the terminal LG to the gate terminal of the low-side transistor LTr is delayed. Since the semiconductor device having this configuration performs high-speed switching in which the control signal is switched a plurality of times in a short period of time, delay of the control signal may lead to malfunction of the semiconductor device, which is undesirable.

In the configuration according to the second embodiment, wires 26d and 26e having high inductance are provided as conductors connecting the conductor pattern 26a and the conductor pattern 26c and connecting the conductor pattern 26b and the conductor pattern 26c, respectively, in the low-side transistor. Due to this effect, the inductance of the circuit connecting the terminal LS and the source terminal of the transistor 32a and the inductance of the circuit connecting the terminal LS and the source terminal of the transistor 32b are increased.

Further, the wires 25d and 26d are arranged adjacent to each other so as to be aligned. Therefore, a mutual induction is exerted between the inductance of the wire 25d and the inductance of the wire 26d. Similarly, the wires 25e and 26e are arranged adjacent to each other so as to be aligned. Therefore, a mutual induction is exerted between the inductance of the wire 25e and the inductance of the wire 26e.

When the low-side gate control voltage is applied to the gate terminal of the transistor 32a, a current flows through the wire 25d from the terminal LG toward the gate terminal of the transistor 32a. On the other hand, when the low-side source control voltage is applied to the source terminal of the transistor 32a, a current flows through the wire 26d from the source terminal of the transistor 32a toward the terminal LS. Therefore, when the control voltage is applied to the transistor 32a, a current flows through the wires 25d and 26d in directions facing each other. As a result, the inductances of the wires 25d and 26d cancel each other due to the mutual induction between the wires 25d and 26d. In addition, due to a similar effect, when the control voltage is applied to the transistor 32b, the inductances of the wires 25e and 26e cancel each other due to the mutual induction between the wires 25e and 26e. As described above, an inductance of the circuit connecting the terminal LG and the gate terminal of the low-side transistor LTr and an inductance of the circuit connecting the terminal LS and the source terminal of the low-side transistor LTr both decrease when the control voltage is applied. This effect suppresses the delay of the control signal caused by the increase in inductance.

Furthermore, since the circuits connected to the two terminals N are short-circuited to each other outside, the inductance between the source terminal of the transistor 32a and the source terminal of the transistor 32b connected via the wires 26d and 26e decreases. On the other hand, the inductance between the gate terminal of the transistor 32a and the gate terminal of the transistor 32b connected via the wires 25d and 25e remains high. Therefore, in the circuit that connects the terminals of the low-side transistors LTr to each other, the Lg/Ls ratio becomes large, so that the oscillation of the low-side transistors can be suppressed. At this time, since almost no current flows through the wires 26d and 26e, cancellation of the inductances due to the mutual induction does not occur. Therefore, a decrease in inductance between the gate terminal of the transistor 32a and the gate terminal of the transistor 32b does not occur.

The semiconductor device 1A according to the second embodiment described above can be variously modified similarly to the semiconductor device 1 according to the first embodiment.

The configuration for connecting the conductor pattern 26a and the conductor pattern 26c and the configuration for connecting the conductor pattern 26b and the conductor pattern 26c are not limited to wires. For example, the conductive portion 26 may connect the conductor pattern 26a and the conductor pattern 26c, and connect the conductor pattern 26b and the conductor pattern 26c by using a flat conductor having a meandering shape folded a plurality of times instead of the wires 26d and 26e. At this time, the conductive portion 25 connects the conductor pattern 25a and the conductor pattern 25c, and connects the conductor pattern 25b and the conductor pattern 25c by using a flat conductor having a meandering shape folded a plurality of times instead of the wires 25d and 25e. A conductor having a meandering shape that is folded a plurality of times has a higher inductance than a conductor having a straight shape. The conductor connecting the conductor pattern 25a and the conductor pattern 25c and the conductor connecting the conductor pattern 26a and the conductor pattern 26c are provided side by side in the Z direction, for example, and a distance between the two conductors is about 0.1 mm and 2 mm or less at the maximum. The conductor connecting the conductor pattern 25b and the conductor pattern 25c and the conductor connecting the conductor pattern 26b and the conductor pattern 26c are provided side by side in the Z direction, for example, and the distance between the two conductors is about 0.1 mm and 2 mm or less at the maximum.

Also, the conductive portion 26 may connect the conductor pattern 26a and the conductor pattern 26c, and connect the conductor pattern 26b and the conductor pattern 26c by using a flat conductor having a shape shorter in a width than the conductor patterns 26a, 26b, and 26c instead of the wires 26d and 26e. At this time, the conductive portion 25 connects the conductor pattern 25a and the conductor pattern 25c, and connects the conductor pattern 25b and the conductor pattern 25c using a flat conductor having a shape having a shorter width than the conductor patterns 25a, 25b, and 25c, instead of the wires 25d and 25e. A conductor having a shape with a short width has a higher inductance than a conductor having a shape with a long width. The conductor connecting the conductor pattern 25a and the conductor pattern 25c and the conductor connecting the conductor pattern 26a and the conductor pattern 26c are provided side by side in the Z direction, for example, and a distance between the two conductors is about 0.1 mm and 2 mm or less at the maximum. The conductor connecting the conductor pattern 25b and the conductor pattern 25c and the conductor connecting the conductor pattern 26b and the conductor pattern 26c are provided side by side in the Z direction, for example, and the distance between the two conductors is about 0.1 mm and 2 mm or less at the maximum.

With the configuration according to the above modification, as in the second embodiment, it is possible to suppress delay of a control signal input from the outside, and further, it is possible to suppress oscillation of a transistor.

Other than the above modifications, various modifications can be considered for the configuration corresponding to the wires 26d and 26e in the second embodiment. The shape is not limited as long as the configuration corresponding to the wires 26d and 26e in the second embodiment and the configuration corresponding to the wires 25d and 25e in the second embodiment are provided so as to be aligned and cancel each other's inductance.

### 3.Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first conductive portion, a second conductive portion, a third conductive portion, and a fourth conductive portion provided on the substrate;
a first transistor having a drain electrically connected to the first conductive portion and a source electrically connected to the second conductive portion; and
a second transistor and a third transistor each having a drain electrically connected to the second conductive portion, a source electrically connected to the third conductive portion, and a gate electrically connected to the fourth conductive portion;
wherein
the second conductive portion includes a first portion in contact with the second transistor and a second portion in contact with the third transistor and located on a side opposite to the first portion with respect to the first conductive portion,
the third conductive portion includes a third portion to which the source of the second transistor is connected and located on a side opposite to the first conductive portion with respect to the first portion, a fourth portion to which the source of the third transistor is connected and located on a side opposite to the first conductive portion with respect to the second portion, and a fifth portion electrically connecting the third portion and the fourth portion, and
the fourth conductive portion includes a sixth portion to which the gate of the second transistor is connected and located on a side opposite to the first conductive portion with respect to the third portion, a seventh portion to which the gate of the third transistor is connected and located on a side opposite to the first conductive portion with respect to the fourth portion, and an eighth portion electrically connecting the sixth portion and the seventh portion, and
a shape of the eighth portion is different from a shape of the sixth portion and a shape of the seventh portion.

2. The semiconductor device according to claim 1, wherein
the sixth portion and the seventh portion of the fourth conductive portion include a conductor pattern, and
the eighth portion of the fourth conductive portion includes a wire.

3. The semiconductor device according to claim 2, wherein a wire included in the eighth portion of the fourth conductive portion is provided so as not to pass over all conductor patterns provided on the substrate.

4. The semiconductor device according to claim 1, wherein
the sixth portion, the seventh portion, and the eighth portion of the fourth conductive portion are continuous conductor patterns, and
the eighth portion of the fourth conductive portion includes a meandering portion.

5. The semiconductor device according to claim 1, wherein
the sixth portion, the seventh portion, and the eighth portion of the fourth conductive portion are continuous conductor patterns, and
a width of the eighth portion of the fourth conductive portion is shorter than a width of the sixth portion and a width of the seventh portion.

6. The semiconductor device according to claim 1, wherein a shape of the fifth portion of the third conductive portion is different from a shape of the third portion and a shape of the fourth portion.

7. The semiconductor device according to claim 6, wherein
the third portion and the fourth portion of the third conductive portion and the sixth portion and the seventh portion of the fourth conductive portion include a conductor pattern, and
the fifth portion of the third conductive portion and the eighth portion of the fourth conductive portion include a wire.

8. The semiconductor device according to claim 7, wherein wires included in the fifth portion of the third conductive portion and the eighth portion of the fourth conductive portion are provided not to pass over all conductor patterns provided on the substrate.

9. The semiconductor device according to claim 6, wherein
the third portion, the fourth portion, and the fifth portion of the third conductive portion are continuous conductor patterns, and
the sixth portion, the seventh portion, and the eighth portion of the fourth conductive portion are continuous conductor patterns, and
each of the fifth portion of the third conductive portion and the eighth portion of the fourth conductive portion includes a meandering portion.

10. The semiconductor device according to claim 6, wherein
the third portion, the fourth portion, and the fifth portion of the third conductive portion are continuous conductor patterns, and
the sixth portion, the seventh portion, and the eighth portion of the fourth conductive portion are continuous conductor patterns, and
a width of the fifth portion of the third conductive portion is shorter than a width of each of the third portion and the fourth portion of the third conductive portion, and
a width of the eighth portion of the fourth conductive portion is shorter than a width of each of the sixth portion and the seventh portion of the fourth conductive portion.

11. The semiconductor device according to claim 6, wherein the fifth portion of the third conductive portion and the eighth portion of the fourth conductive portion are both separated from each other, and are provided side by side with an interval of 2 mm or less.

12. The semiconductor device according to claim 7, wherein the fifth portion of the third conductive portion and the eighth portion of the fourth conductive portion are both separated from each other, and are provided side by side with an interval of 2 mm or less.

13. The semiconductor device according to claim 8, wherein the fifth portion of the third conductive portion and the eighth portion of the fourth conductive portion are both separated from each other, and are provided side by side with an interval of 2 mm or less.

14. The semiconductor device according to claim 9, wherein the fifth portion of the third conductive portion and the eighth portion of the fourth conductive portion are both separated from each other, and are provided side by side with an interval of 2 mm or less.

15. The semiconductor device according to claim 10, wherein the fifth portion of the third conductive portion and the eighth portion of the fourth conductive portion are both separated from each other, and are provided side by side with an interval of 2 mm or less.
